(19) United States
(12) Patent Application Publication
(10) Pub. No.: US 2002/0110978 A1
(43) Pub. Date: Aug. 15, 2002

(54) Method for treating the surface of a bit line conductive layer

(76) Inventor: King-Lung Wu, Tainan (TW)

Correspondence Address: POWELL, GOLDSTEIN, FRAZER & MURPHY LLP, P.O. BOX 97233, WASHINGTON, DC, 20090-7233, US

(21) Appl. No.: 09/783,847

(22) Filed: Feb. 15, 2001

(51) Int. Cl. H01L 21/8242

(52) U.S. Cl. 438/241

(57) ABSTRACT

A method for treating the surface of a bit line conductive layer is provided. A semiconductor substrate having a bit line contact diffusion layer formed therein is provided firstly. Then, forming a dielectric layer on the substrate. Next, forming a bit line contact in the dielectric layer and abutting the surface of the bit line contact diffusion layer. Forming a first conductive layer on the dielectric layer and the bit line contact. Then, patterning the first conductive layer. Finally, applying an oxygen plasma treatment onto the surface of the patterned first conductive layer. After the oxygen plasma treatment, the electric charges are more uniformly distributed on the surface of the patterned first conductive layer, and not concentrated on a certain surface area thereof. Therefore, the residue etchant gases during the formation of the bit line contact could not be attracted and concentrated on this surface area. The broken bit line formed of the first conductive layer would be prevented.

### BACKGROUND OF THE INVENTION

1. Field of the Invention

The present invention relates to a semiconductor process; and more particularly to a method for fabricating a DRAM (Dynamic Random Access Memory) device.

2. Description of the Prior Art

DRAM memory cells are a well-known class of semiconductor devices in the art. These devices provide a means of temporary data storage, and they are used in many digital systems, such as computers.

Because intense competition in the DRAM marketplace, it is essential that manufacturers reduce the cost of their DRAM memory circuits. To reduce costs and to meet customer expectations for decreasing access times and increasing IC memory sizes, manufacturers must continually reduce the size of features on the integrated circuit wafer. Such reductions in feature size have brought about much advancement in the art. However, the small geometry presents problems in the predictable manufacture of DRAM circuits.

One manufacturing problem is illustrated in the partially completed prior DRAM cell depicted in FIG. 1. In this schematic view, the DRAM cell contains a substrate 11 typically composed of lightly doped P type monocrystalline silicon, and a NMOS transistor 12 formed on the substrate 11 with the gate thereof serving as a word line. The source/drain 13 of the NMOS transistor 12 is used as a bit line contact diffusion layer. While the other source/drain 14 of the NMOS transistor is connected to a storage capacitor (not shown in the figure) for storing the charge on the cell. A polysilicon bit line contact 16 is formed in a dielectric layer 15 on the substrate 11 and abut the surface of the bit line contact diffusion layer 13. A polysilicon bit line 17 is formed on the polysilicon bit line contact 16. The NMOS transistor 12 allows the polysilicon bit line 17 to access the charge-storage region of the capacitor. In operation, the charge initially enters the cell from the polysilicon bit line 17, through the polysilicon bit line contact 16, and thereafter passes through the bit line contact diffusion layer 13 into the capacitor.

To form the polysilicon bit line contact 16, a self-aligned contact opening is firstly formed in the dielectric layer 15 abutting the surface of the bit line contact diffusion layer 13, through a photolithography and etching method. Then, depositing a polysilicon layer on the dielectric layer 15 to fill the self-aligned contact opening, and anisotropically etching the polysilicon layer, by way of, such as reactive ion etching method, utilizing the mixture gases of HBr, Cl₂ and HCl as the etchant gases. Thereby, the polysilicon bit line contact 16 is obtained. During the etching process, the residue etchant gases of HBr, Cl₂ and HCl are easily adsorbed on the exposed substrate 11 in the self-aligned contact opening. Moreover, the electric charges will subject to concentrate on a certain surface area of the polysilicon bit line 17 subsequently formed if there is no specific treatment applied onto the surface thereof. The residue etchant gases will be attracted and concentrated on the certain surface area that the electric charges are accumulated, and then etch the polysilicon bit line 17, resulting that a portion of the polysilicon bit line 17 becomes thinner and even broken, which especially occurs in the proximity of the polysilicon bit line contact 16, seeing the dotted line in FIG. 1, and as shown in FIGS. 2A and 2B.

Accordingly, it is desirable to provide a method for treating the surface of the bit line and alleviating the drawback encountered in the prior art.

### SUMMARY OF THE INVENTION

It is one object of the present invention to provide a method for treating the surface of a bit line conductive layer, in which an oxygen plasma treatment is implemented onto the surface of the bit line conductive layer, in order that electric charges could be more uniformly distributed on the surface of the bit line conductive layer. Thereby, the residue etchant gases due to forming a bit line contact would not be attracted and concentrated on a certain surface of the bit line conductive layer. Therefore, a bit line broken could be prevented.

It is another object of the present invention to provide a method for treating the surface of a bit line conductive layer, in which an oxygen plasma treatment could be implemented onto the surface of an antireflective coating layer formed on the bit line conductive layer, so that electric charges are more uniformly distributed on the surface of the anti-reflective coating layer. The residue etchant gases from the formation of a bit line contact would not be attracted and concentrated on a certain surface of the anti-reflective coating layer. And thus, the broken bit line could be prevented.

In order to achieve the above objects, the present invention provides a method for treating the surface of a bit line conductive layer. A semiconductor substrate having a bit line contact diffusion layer formed therein is provided firstly. Then, forming a dielectric layer on the substrate. Next, forming a bit line contact in the dielectric layer and abutting the surface of the bit line contact diffusion layer. Forming a first conductive layer on the dielectric layer and the bit line contact. Then, patterning the first conductive layer. Finally, applying an oxygen plasma treatment onto the surface of the patterned first conductive layer. After the oxygen plasma treatment, the electric charges are more uniformly distributed on the surface of the patterned first conductive layer, and not concentrated on a certain surface area thereof. Therefore, the residue etchant gases during the formation of the bit line contact could not be attracted and concentrated on this surface area. The broken bit line formed of the first conductive layer would be prevented.

### BRIEF DESCRIPTION OF THE DRAWINGS

The foregoing and other advantages and features of the invention will be apparent from the following more particular description of preferred embodiments of the invention, as illustrated in the accompanying drawings.

FIG. 1 depicts a partial cross-sectional view of a cell of a prior DRAM device;

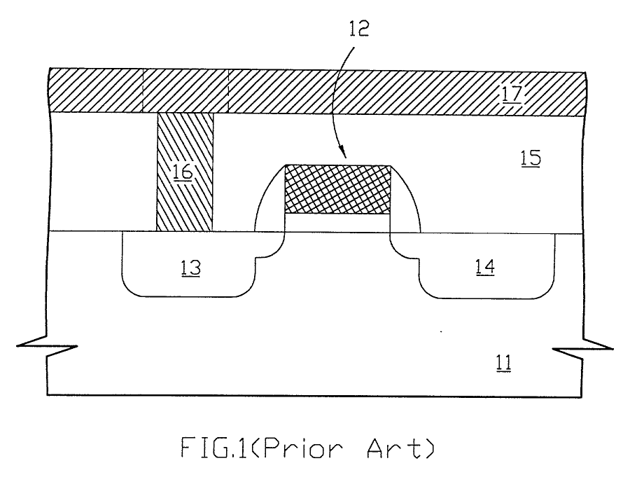

FIGS. 2A and 2B respectively depicts a partial top view of FIG. 1, showing that the polysilicon bit line in the proximity of the bit line contact becomes thinner and even broken;

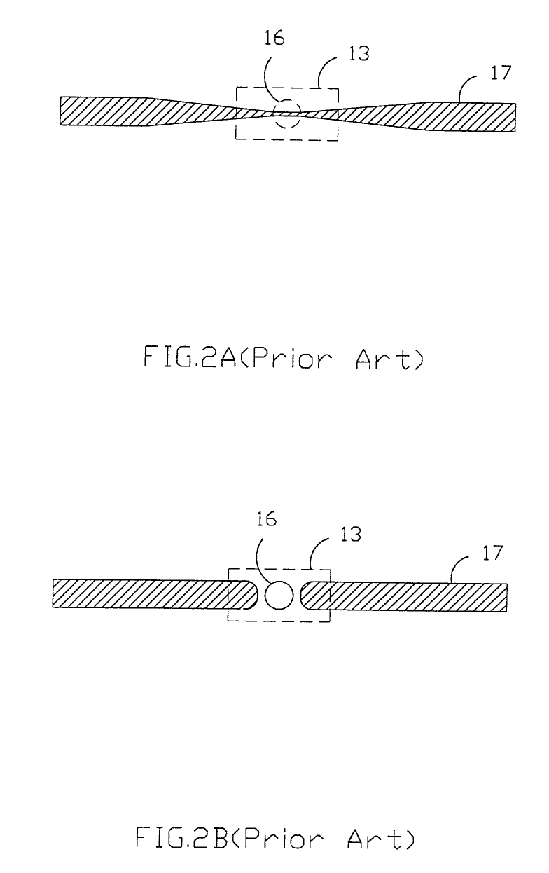

FIG. 3 depicts a flow chart of the present invention; and

FIG. 4 depicts a partial cross-sectional view of a DRAM cell according to the present invention.

### DESCRIPTION OF THE PREFERRED EMBODIMENTS

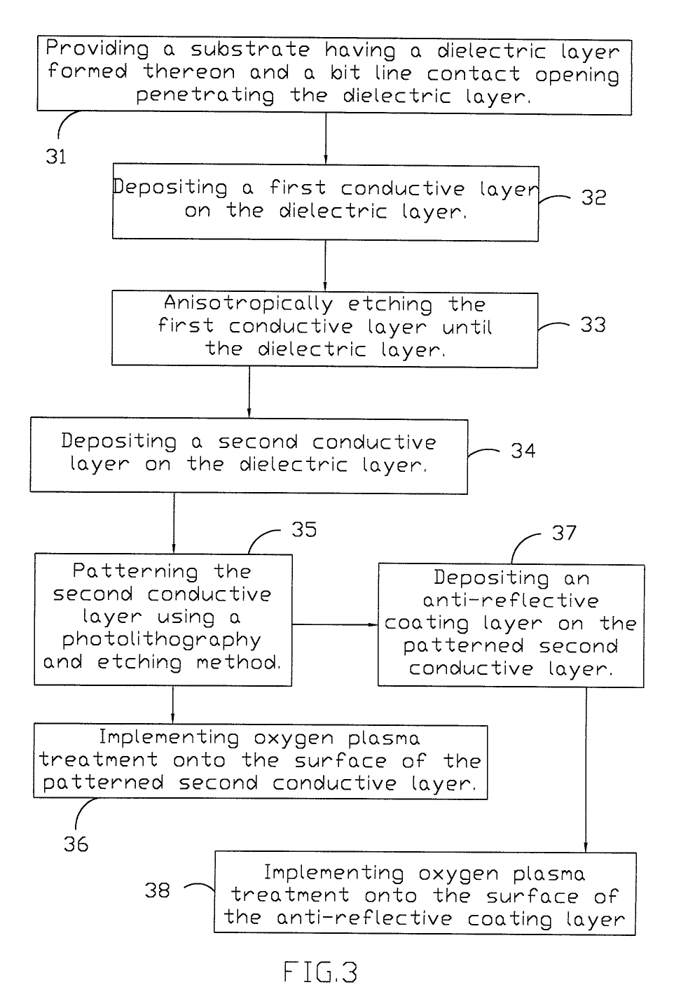

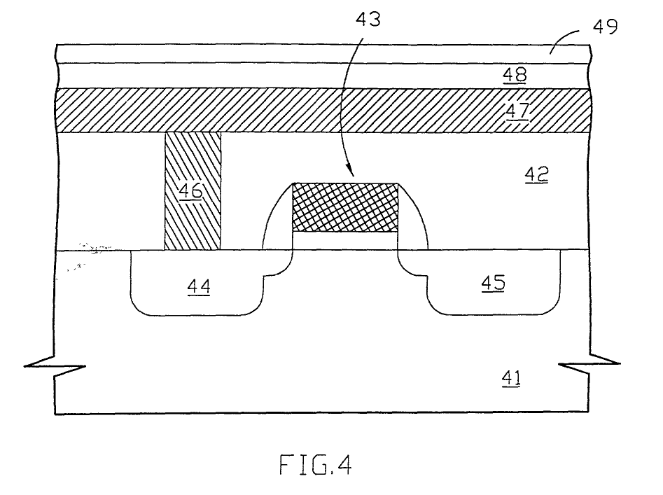

As mentioned in the foregoing, to avoid the electric charges accumulating in a certain surface area of a bit line conductive layer, the present invention employs an oxygen plasma treatment onto the surface of the bit line conductive layer. The flow chart of the present method is shown in FIG. 3. And, FIG. 4 shows a partial cross-sectional view of a DRAM cell according to the present invention, wherein the oxygen plasma treatment is applied onto the top surface of the DRAM cell of FIG. 4.

For the step 31, firstly, providing a semiconductor substrate 41 having a dielectric layer 42 formed thereon and a bit line contact opening penetrating the dielectric layer 42. The semiconductor substrate 41 is typically composed of P type monocrystalline silicon. The semiconductor substrate 41 also contains an NMOS transistor 43 with the gate thereof serving as a word line, and the source/drain 44 is used as a bit line contact diffusion layer. The other source/drain 45 is connected to a storage capacitor (not shown in the figure). The dielectric layer 42 can be a silicon dioxide layer formed by the conventional chemical vapor deposition methods. And, the bit line contact opening can be a self-aligned contact opening formed by way of the conventional photolithography and anisotropically etching method.

Then, for the step 32, depositing a first conductive layer on the dielectric layer 42 to fill the bit line contact opening. The first conductive layer can be a polysilicon layer formed of the conventional chemical vapor deposition method, such as low pressure chemical vapor deposition (LPCVD).

Next, for the step 33, anisotropically etching the first conductive layer to form a bit line contact 46. When the first conductive layer is formed of polysilicon, the polysilicon layer can be etched by way of reactive ion etching method using the gas mixture of HBr, Cl₂ and HCl serving as the etchant gases to form the polysilicon bit line contact.

Subsequently, for the step 34, depositing a second conductive layer 47 with a thickness about 1000 angstroms on the dielectric layer 42. The second conductive layer 47 can be a polysilicon layer formed by way of the conventional chemical vapor deposition methods, such as low pressure chemical vapor deposition (LPCVD).

Followed by the step 35, patterning the second conductive layer 47 to form a bit line through a photolithography and etching method. When the second conductive layer 47 is formed of polysilicon, the gas mixture of HBr, Cl₂ and HCl can be used as the etchant gas and proceeding anisotropically etching by way of reactive ion etching method, to form the polysilicon bit line.

Finally, followed by the step 36, implementing an oxygen plasma treatment onto the surface of the patterned second conductive layer 47. The oxygen plasma treatment employes oxygen gas (O₂) for providing oxygen ions. Therein, the flow rate of oxygen gas is about 3000˜4200 sccm. In more detail, the oxygen plasma treatment is implemented under the conditions of 600˜800 W for power, 250° C. in temperature and 1.1˜1.3 torr in pressure for 30˜60 seconds.

Alternately, the step 35 is followed by the step 37 and then the step 38. For the step 37, an anti-reflective coating layer 49 with a thickness about 400 angstroms can be formed on the patterned second conductive layer 47 prior to proceeding the oxygen plasma treatment. Then, the oxygen plasma treatment is applied onto the surface of the anti-reflective coating layer 49. The anti-reflective coating layer 49 can be a silicon oxynitride layer formed by way of plasma enhanced chemical vapor deposition method utilizing the reaction gases of SiH₄, N₂O and N₂.

Besides, when the second conductive layer 47 is formed of a polysilicon layer, another conductive layer 48, such as a tungsten silicide (WSi₂) layer, with a thickness about 1000 angstroms can be formed between the polysilicon layer and the anti-reflective coating layer 49, to reduce the resistance of the polysilicon layer.

Finally, followed by the step 38, implementing the oxygen plasma treatment the same with the above-mentioned onto the surface of the anti-reflective coating layer 49.

According to the foregoing, the oxygen plasma treatment is applied onto the surface of the bit line conductive layer 47, or the anti-reflective coating layer 49 formed thereon. The electric charges would be more uniformly distributed on the surface treated by the oxygen plasma and not be concentrated on a certain surface area having been treated. Therefore, the residue etchant gases of HBr, Cl₂ and HCl will not be adsorbed and concentrated on the certain surface area. Hence, the residue etchant gases would not etch the bit line conductive layer, and the bit line broken would be prevented.

The preferred embodiments are only used to illustrate the present invention, not intended to limit the scope thereof. Many modifications of the preferred embodiments can be made without departing from the spirit of the present invention.

What is claimed is:

1. A method for treating the surface of a bit line conductive layer, comprising:
providing a semiconductor substrate having a bit line contact diffusion layer formed therein;
forming a dielectric layer on said substrate;
forming a bit line contact in said dielectric layer and abutting the surface of said bit line contact diffusion layer;
forming a first conductive layer on said dielectric layer and said bit line contact;
patterning said first conductive layer; and
applying oxygen plasma treatment onto the surface of said patterned first conductive layer.

2. The method of claim 1, wherein said dielectric layer is formed of silicon dioxide.

3. The method of claim 1, wherein said bit line contact comprises a polysilicon plug.

4. The method of claim 1, wherein the steps of forming said bit line contact comprises patterning said dielectric layer and forming a second conductive layer on said patterned dielectric layer, and then anisotropically etching said second conductive layer until exposing said dielectric layer.

5. The method of claim 3, wherein the steps of forming said bit line contact comprises patterning said dielectric layer and forming a first polysilicon layer on said patterned dielectric layer by way of LPCVD method, and then anisotropically etching said first polysilicon layer until said dielectric layer.

6. The method of claim 5, wherein said first polysilicon layer is anisotropically etched by way of reactive ion etching method using the gas mixture of HBr, Cl₂ and HCl as etchant gases.

7. The method of claim 1, wherein said first conductive layer comprises a second polysilicon layer.

8. The method of claim 1, wherein the steps of patterning said first conductive layer comprises a photolithography and anisotropically etching processes.

9. The method of claim 7, wherein the steps of patterning said second polysilicon layer comprises a photolithography and etching processes by way of reactive ion etching method using a gas mixture of HBr, Cl2 and HCl as etchant gases.

10. The method of claim 1, wherein said oxygen plasma treatment employs oxygen gas (O₂) to provide oxygen ions.

11. The method of claim 1, wherein said oxygen treatment is implemented under the condition of about 250° C. in temperature.

12. The method of claim 1, wherein said oxygen treatment is implemented under the condition of about 1.1˜1.3 torr in pressure.

13. The method of claim 1, wherein said oxygen plasma treatment is implemented for 30˜60 seconds.

14. The method of claim 1, wherein said oxygen plasma treatment is implemented under the conditions of about 600˜800 W for power, about 250° C. in temperature and about 1.1˜1.3 torr in pressure and for 30˜60 seconds.

15. The method of claim 1, wherein an anti-reflective coating layer is formed on said first conductive layer prior to implement said oxygen plasma treatment.

16. The method of claim 1, wherein said anti-reflective coating layer comprises a silicon oxynitride (SiON) layer.

17. The method of claim 16, wherein said silicon oxynitride layer is formed by way of plasma enhanced chemical vapor deposition method utilizing reaction gases of SiH₄, N₂O and N₂.

18. The method of claim 15, wherein said oxygen plasma treatment employs oxygen gas (O₂) to provide oxygen ions.

19. The method of claim 15, wherein said oxygen treatment is implemented under the condition of about 250° C. in temperature.

20. The method of claim 15, wherein said oxygen treatment is implemented under the condition of about 1.1˜1.3 torr in pressure.

21. The method of claim 15, wherein said oxygen plasma treatment is implemented for 30˜60 seconds.

22. The method of claim 15, wherein said oxygen plasma treatment is implemented under the conditions of about 600˜800 W for power, about 250° C. in temperature and 1.1˜1.3 torr in pressure and for 30˜60 seconds.

23. The method of claim 16, wherein said oxygen plasma treatment employs oxygen gas (O₂) to provide oxygen ions.

24. The method of claim 16, wherein said oxygen treatment is implemented under the condition of about 250° C. in temperature.

25. The method of claim 16, wherein said oxygen treatment is implemented under the condition of 1.1˜1.3 torr in pressure.

26. The method of claim 16, wherein said oxygen plasma treatment is implemented for 30˜60 seconds.

27. The method of claim 16, wherein said oxygen plasma treatment is implemented under the conditions of about 600˜800 W for power, about 250° C. in temperature and about 1.1˜1.3 torr in pressure and for 30˜60 seconds.

28. The method of claim 7, wherein an anti-reflective coating layer is formed on said second polysilicon layer prior to implementing said oxygen plasma treatment.

29. The method of claim 28, wherein said anti-reflective coating layer comprises a silicon oxynitride layer.

30. The method of claim 28, wherein said silicon oxynitride layer is formed by way of plasma enhanced chemical vapor deposition method utilizing reaction gases of SiH₄, N₂O and N₂.

31. The method of claim 28, wherein said oxygen plasma treatment employs oxygen gas (O₂) to provide oxygen ions.

32. The method of claim 28, wherein said oxygen treatment is implemented under the condition of about 250° C. in temperature.

33. The method of claim 28, wherein said oxygen treatment is implemented under the condition of about 1.1˜1.3 torr in pressure.

34. The method of claim 28, wherein said oxygen plasma treatment is implemented for 30˜60 seconds.

35. The method of claim 28, wherein said oxygen plasma treatment is implemented under the conditions of about 600˜800 W for power, about 250° C. in temperature and about 1.1˜1.3 torr in pressure and for 30˜60 seconds.

36. The method of claim 29, wherein said oxygen plasma treatment employs oxygen gas (O₂) to provide oxygen ions.

37. The method of claim 29, wherein said oxygen treatment is implemented under the condition of about 250° C. in temperature.

38. The method of claim 29, wherein said oxygen treatment is implemented under the condition of about 1.1˜1.3 torr in pressure.

39. The method of claim 29, wherein said oxygen plasma treatment is implemented for 30˜60 seconds.

40. The method of claim 29, wherein said oxygen plasma treatment is implemented under the conditions of about 600˜800 W for power, about 250° C. in temperature and about 1.1˜1.3 torr in pressure and for 30˜60 seconds.

41. A method for treating the surface of a polysilicon bit line, comprising:
providing a semiconductor substrate having a bit line contact diffusion layer formed therein;
forming a dielectric layer on said substrate;
forming a polysilicon bit line contact in said dielectric layer and abutting the surface of said bit line contact diffusion layer;
forming a first polysilicon layer on said dielectric layer and said polysilicon bit line contact;
patterning said first polysilicon layer to form said polysilicon bit line; and
applying oxygen plasma treatment onto the surface of said polysilicon bit line.

42. The method of claim 41, wherein said dielectric layer is formed of silicon dioxide.

43. The method of claim 41, wherein the steps of forming said polysilicon bit line contact comprises patterning said dielectric layer and forming a second polysilicon layer on said patterned dielectric layer by way of LPCVD method, and then etching said second polysilicon layer until exposing said dielectric layer by way of reactive ion etching method using a gas mixture of HBr, Cl2 and HCl as etchant gases.

44. The method of claim 41, wherein the steps of patterning said first polysilicon layer comprises a photolithography and etching processes by way of reactive ion etching method using a gas mixture of HBr, Cl2 and HCl as etchant gases.

45. The method of claim 41, wherein an anti-reflective coating layer of silicon oxynitride is formed on said first polysilicon layer prior to implementing said oxygen plasma treatment.

46. The method of claim 41, wherein said oxygen plasma treatment employs oxygen gas (O₂) to provide oxygen ions.

47. The method of claim 41, wherein said oxygen treatment is implemented under the condition of about 250° C. in temperature.

48. The method of claim 41, wherein said oxygen treatment is implemented under the condition of about 1.1˜1.3 torr in pressure.

49. The method of claim 41, wherein said oxygen plasma treatment is implemented for 30˜60 seconds.

50. The method of claim 41, wherein said oxygen plasma treatment is implemented under the conditions of about 600˜800 W for power, about 250° C. in temperature and about 1.1˜1.3 torr in pressure and for 30˜60 seconds.

51. The method of claim 45, wherein said oxygen plasma treatment employs oxygen gas (O₂) to provide oxygen ions.

52. The method of claim 45, wherein said oxygen treatment is implemented under the condition of about 250° C. in temperature.

53. The method of claim 45, wherein said oxygen treatment is implemented under the condition of about 1.1˜1.3 torr in pressure.

54. The method of claim 45, wherein said oxygen plasma treatment is implemented for 30˜60 seconds.

55. The method of claim 45, wherein said oxygen plasma treatment is implemented under the conditions of about 600˜800 W for power, about 250° C. in temperature and about 1.1˜1.3 torr in pressure and for 30˜60 seconds.
